(19) United States
(12) Patent Application Publication
(10) Pub. No.: US 2018/0294294 A1
(43) Pub. Date: Oct. 11, 2018

(54) FLAT PLATE TYPE OF IMAGE SENSOR

(71) Applicant: SILICON DISPLAY TECHNOLOGY, Yongin-si (KR)

(72) Inventors: Jae Min KIM, Daegu (KR); Ki Joong KIM, Suwon-si (KR); Ji Ho HUR, Yongin-si (KR)

(21) Appl. No.: 15/767,417

(22) PCT Filed: Nov. 6, 2015
(86) PCT No.: PCT/KR2015/011877

§ 371 Date: Apr. 11, 2018

(51) Int. Cl. H01L 27/146; H01L 31/16

(52) U.S. Cl. CPC H01L 27/1464; H01L 31/16; H01L 27/14614

(57) ABSTRACT

The present invention relates to a flat plate type of image sensor including: a backlight unit for emitting at least one light from among visible light, infrared light, and ultraviolet light at an object; a visible light conversion unit for converting ultraviolet light reflected from the object into visible light; and a photosensor unit for sensing at least one from among the visible light emitted from the backlight unit and reflected from the object, the infrared light emitted from the backlight unit and reflected from the object, and the visible light converted in the visible light conversion unit.

### BACKGROUND OF THE INVENTION

### (a) Field of the Invention

An exemplary embodiment of the present invention relates to a flat plate type of image sensor.

### (b) Description of the Related Art

An image sensor is a device that obtains an image by using a property that a semiconductor reacts to light.

In the image sensor, pixels sense brightness and wavelengths of different light coming out from each object and convert them into electrical values. The image sensor plays a role of converting these electrical values (code values) to signal-treatable levels.

In general, an image sensor according to a conventional art is composed of a thin film transistor and a photosensor. Specifically, in the image sensor according to a conventional art, the thin film transistor is fabricated by depositing a semiconductor, a gate electrode, an insulation layer, a data electrode, and the like, and the photosensor is fabricated by depositing a first electrode, a photosensor unit, a second electrode, and the like.

However, the image sensor according to a conventional art uses a backlight unit emitting visible light that is sensed by eyes of a user, and thus has a drawback of not sensing light in more various wavelength regions.

### SUMMARY OF THE INVENTION

### Technical Object

The present invention provides a flat plate type of image sensor sensing light of more various wavelength regions by using a backlight unit emitting visible light, infrared light, or ultraviolet (UV) light in order to solve the above problem.

In addition, the present invention improves security of a document and the like by using an ultraviolet (UV) or infrared light backlight to sense an image reflecting the ultraviolet (UV) and infrared light which is produced to not be sensed by eyes of a user.

### Technical Solution

A flat plate type of image sensor according to the present exemplary embodiment, in order to solve the problems, includes: a backlight unit for emitting at least one light from among visible light, infrared light, and ultraviolet light at an object; a visible light conversion unit for converting ultraviolet light reflected from the object into visible light, and a photosensor unit for sensing at least one from among the visible light emitted from the backlight unit and reflected from the object, the infrared light emitted from the backlight unit and reflected from the object, and the visible light converted in the visible light conversion unit.

According to another exemplary embodiment of the present invention, the visible light converter may include a UV ink or a quantum dot.

According to another exemplary embodiment of the present invention, the photosensor unit may be composed of one of an amorphous silicon photodiode, an organic material photosensor, and a quantum dot photosensor.

According to another exemplary embodiment of the present invention, a switching thin film transistor transmitting a signal of the photosensor unit may be further included.

According to another exemplary embodiment of the present invention, the switching thin film transistor may be composed of one of a coplanar thin film transistor, a staggered thin film transistor, an inverted coplanar thin film transistor, and an inverted staggered thin film transistor.

According to another exemplary embodiment of the present invention, the switching thin film transistor may include: an insulation substrate; a semiconductor active layer formed on the insulation substrate; a gate insulating layer formed on the semiconductor active layer; a gate electrode formed on the gate insulating layer; an interlayer insulating layer formed on the gate electrode; a source electrode and a drain electrode formed in a via hole on the gate insulating layer and the interlayer insulating layer; and a first protective layer formed on the switching thin film transistor.

According to another exemplary embodiment of the present invention, the photosensor unit may include: an electrode extended from the drain electrode or the source electrode of the thin film transistor; a semiconductor layer formed on the extended electrode; a transparent electrode formed on the semiconductor layer; a second protective layer formed on the semiconductor layer and the transparent electrode and protecting the photosensor unit; and a bias electrode formed in a via hole formed in the second protective layer and connected to the transparent electrode.

Another exemplary embodiment of the present invention may further include a sensor protective layer formed on the second protective layer and the bias electrode.

According to another exemplary embodiment of the present invention, the semiconductor active layer may be one of a low temperature polycrystalline silicon semiconductor, an amorphous silicon semiconductor, and an oxide semiconductor.

According to another exemplary embodiment of the present invention, the visible light converter may be disposed between the object and the photosensor unit.

According to another exemplary embodiment of the present invention, the second protective layer or sensor protective layer may be formed of an organic material or an inorganic material.

### Advantageous Effects

An exemplary embodiment of the present invention provides a flat plate type of image sensor sensing light in more various wavelength regions by using a backlight unit emitting visible light, infrared light, or ultraviolet (UV) light.

In addition, an exemplary embodiment of the present invention improves security of a document and the like by using an ultraviolet (UV) or infrared light backlight to sense an image reflecting ultraviolet (UV) light and infrared light which is produced to not be sensed by eyes of a user.

### BRIEF DESCRIPTION OF THE DRAWINGS

FIG. 1 is a cross-sectional view showing a flat plate type of image sensor according to an exemplary embodiment of the present invention.

FIG. 2 is a cross-sectional view showing a flat plate type of image sensor according to another exemplary embodiment of the present invention.

### DETAILED DESCRIPTION OF THE EMBODIMENTS

In the following, an exemplary embodiment of the present invention will be described in detail with reference to accompanying drawings. However, in the description of the embodiments, when it is determined that a concrete description of related known functions or configurations unnecessarily obscures the gist of the present invention, a detailed description thereof will be omitted. In addition, a size of each component in the drawings may be exaggerated for ease of explanation, and does not mean the size actually applied.

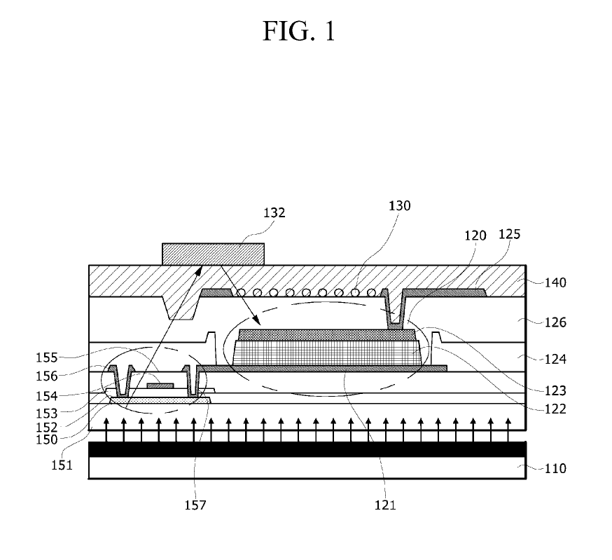

FIG. 1 is a cross-sectional view of a flat plate type of image sensor according to an exemplary embodiment of the present invention.

Referring to FIG. 1, a flat plate type of image sensor according to an exemplary embodiment of the present invention is described.

As shown in FIG. 1, the flat plate type of image sensor according to an exemplary embodiment of the present invention may consist of a backlight unit 110, a photosensor unit 120, a visible light converter 130, and a switching thin film transistor 150.

The backlight unit 110 may be fabricated to emit at least one among visible light, infrared light, and ultraviolet (UV) light, and the backlight unit 110 emits the light to an object 132.

The visible light converter 130 may convert ultraviolet (UV) light reflected from the object 132 into visible light.

In other words, when the ultraviolet (UV) light is emitted from the backlight unit 110 and reflected at the object 132, the visible light converter 130 receives the ultraviolet (UV) light reflected at the object 132 and converts it into visible light.

The photosensor unit 120 senses light radiated by the backlight unit 110 and reflected at the object 132.

In other words, the photosensor unit 120 may sense at least one of visible light reflected at the object 132 after being emitted by the backlight unit 110, infrared light, and the visible light converted in the visible light converter 130.

On the other hand, the visible light converter 130 may be fabricated to include a UV ink or a quantum dot and be disposed between the object 132 and the photosensor unit 120.

The photosensor unit 120 may be composed of one of an amorphous silicon photodiode, an organic material photosensor, and a quantum dot photosensor.

The switching thin film transistor 150 transports a signal of the photosensor unit 120, and may be composed of one of coplanar, staggered, inverted coplanar, and inverted staggered thin film transistors.

In more detail, the switching thin film transistor 150 includes an insulation substrate 151, a semiconductor active layer 152 formed on the insulation substrate 151, a gate insulating layer 153 formed on the semiconductor active layer 152, a gate electrode 154 formed on the gate insulating layer 153, an interlayer insulating layer 155 formed on the gate electrode 154, and a source electrode 156 and a drain electrode 157 (or a source electrode 157 and a drain electrode 156) formed in a via hole formed in the interlayer insulating layer 155 and the gate insulating layer 153, and a first protective layer 124 is formed thereon. Herein, the first protective layer 124 protects the switching thin film transistor 150.

Alternatively, the photosensor unit 120 may include a semiconductor layer 122 formed on an electrode 121 extended from a drain electrode or a source electrode 157 of the switching thin film transistor 150, a transparent electrode 123 formed on the semiconductor layer 122, a second protective layer 126 formed on the semiconductor layer 122 and the transparent electrode 123, and a bias electrode 125 formed in a via hole formed in the second protective layer 126 and connected to the transparent electrode 123. Herein, the second protective layer 126 protects the photosensor unit 120.

In addition, a sensor protective layer 140 may be formed on the second protective layer 126 and the bias electrode 125, and the second protective layer 126 or the sensor protective layer 140 may be formed of an organic material or an inorganic material.

Accordingly, an exemplary embodiment of the present invention may provide a flat plate type of image sensor sensing light of more various wavelength regions by using a backlight unit emitting visible light, infrared light, or ultraviolet (UV) light.

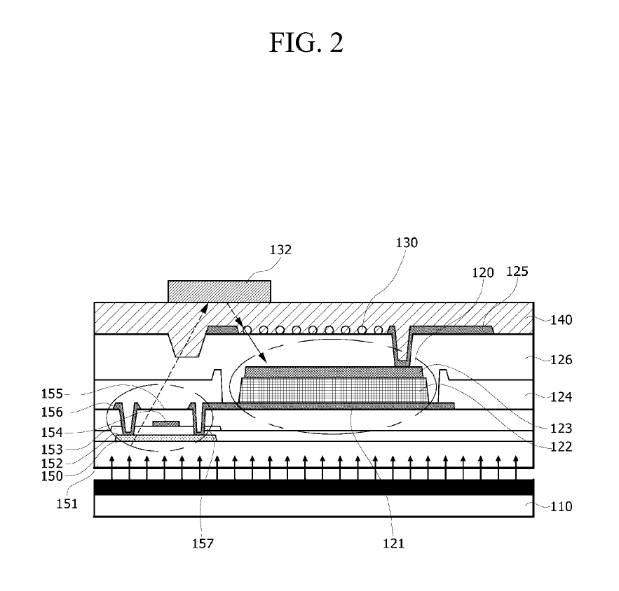

FIG. 2 is a cross-sectional view of a flat plate type of image sensor according to another exemplary embodiment of the present invention.

Referring to FIG. 2, a flat plate type of image sensor according to another exemplary embodiment of the present invention is described.

Like the embodiment of FIG. 1, a flat plate type of image sensor according to the embodiment of FIG. 2 includes a backlight unit 110, a photosensor unit 120, a visible light converter 130, and a switching thin film transistor 150.

Herein, the backlight unit 110 according to the embodiment of FIG. 2 is fabricated to emit ultraviolet (UV) light, and the backlight unit 110 emits the ultraviolet (UV) light to an upper object 132.

The visible light converter 130 may convert the ultraviolet (UV) light reflected at the object 132 into visible light.

In other words, when the ultraviolet (UV) light emitted from the backlight unit 110 is reflected at the object 132, the visible light converter 130 may receive the ultraviolet (UV) light and convert it into visible light.

The photosensor unit 120 may sense the visible light converted in the visible light converter 130 after it is emitted from the backlight unit 110 and reflected at the object 132.

Herein, the visible light converter 130 may be fabricated to include a UV ink or a quantum dot, and disposed is between the object 132 and the photosensor unit 120.

Meanwhile, the photosensor unit 120 may be composed of one of an amorphous silicon photodiode, an organic material photosensor, and a quantum dot photosensor.

In addition, the switching thin film transistor 150 plays a role of transmitting a signal of the photosensor unit 120, and may be one of coplanar, staggered, inverted coplanar, and inverted staggered thin film transistors.

The switching thin film transistor 150 includes an insulation substrate 151, a semiconductor active layer 152 formed on the insulation substrate 151, a gate insulating layer 153 formed on the semiconductor active layer 152, a gate electrode 154 formed on the gate insulating layer 153, an interlayer insulating layer 155 formed on the gate electrode 154, and a source electrode 156 and a drain electrode 157 (or a source electrode 157 and a drain electrode 156) formed in a via hole formed in the interlayer insulating layer 155 and the gate insulating layer 153. In addition, a first protective layer 124 is formed on the switching thin film transistor 150, and plays a role of protecting the switching thin film transistor 150.

Alternatively, the photosensor unit 120 may include a semiconductor layer 122 formed on an electrode 121 extended from a drain electrode or a source electrode 157 of the switching thin film transistor 150, a transparent electrode 123 formed on the semiconductor layer 122, a second protective layer 126 formed on the semiconductor layer 122 and the transparent electrode 123, and a bias electrode 125 formed in a via hole formed in the second protective layer 126 and connected to the transparent electrode 123.

Herein, the second protective layer 126 protects the photosensor unit 120.

In addition, a sensor protective layer 140 may be formed on the second protective layer 126 and the bias electrode 125, and the second protective layer 126 or the sensor protective layer 140 may be formed of an organic material or an inorganic material.

Therefore, according to an exemplary embodiment of the present invention, an image reflecting ultraviolet (UV) and infrared light but not sensed by eyes of a user may be sensed by using an ultraviolet (UV) or infrared light backlight in order to improve security of a document and the like.

In the detailed description of the present invention as described above, an exemplary embodiment has been described. However, various modifications are possible within the scope of the present invention. The technical idea of the present invention is not restricted to the above-mentioned embodiment of the present invention, and it should be determined not only by the claims, but also by equivalents to the scope of the claims.

What is claimed is:

1. A flat plate type of image sensor, comprising:
a backlight unit for emitting at least one light from among visible light, infrared light, and ultraviolet light at an object;
a visible light conversion unit for converting ultraviolet light reflected from the object into visible light; and
a photosensor unit for sensing at least one from among the visible light emitted from the backlight unit and reflected from the object, the infrared light emitted from the backlight unit and reflected from the object, and the visible light converted in the visible light conversion unit.

2. The flat plate type of image sensor of claim 1, wherein
the visible light converter includes a UV ink or a quantum dot.

3. The flat plate type of image sensor of claim 1, wherein
the photosensor unit is composed of one of an amorphous silicon photodiode, an organic material photosensor, and a quantum dot photosensor.

4. The flat plate type of image sensor of claim 1, which further includes a switching thin film transistor transmitting a signal of the photosensor unit.

5. The flat plate type of image sensor of claim 4, wherein the switching thin film transistor is composed of one of a coplanar thin film transistor, a staggered thin film transistor, an inverted coplanar thin film transistor, and an inverted staggered thin film transistor.

6. The flat plate type of image sensor of claim 4, wherein the switching thin film transistor includes:
an insulation substrate;
a semiconductor active layer formed on the insulation substrate;
a gate insulating layer formed on the semiconductor active layer;
a gate electrode formed on the gate insulating layer;
an interlayer insulating layer formed on the gate electrode;
a source electrode and a drain electrode formed in a via hole formed in the gate insulating layer and the interlayer insulating layer; and
a first protective layer formed on the switching thin film transistor.

7. The flat plate type of image sensor of claim 6, wherein the photosensor unit includes:
an electrode extended from the drain electrode or the source electrode of the thin film transistor;
a semiconductor layer formed on the extended electrode;
a transparent electrode formed on the semiconductor layer;
a second protective layer formed on the semiconductor layer and the transparent electrode and protecting the photosensor unit; and
a bias electrode formed in a via hole formed in the second protective layer and connected to the transparent electrode.

8. The flat plate type of image sensor of claim 7, which further includes a sensor protective layer formed on the second protective layer and the bias electrode.

9. The flat plate type of image sensor of claim 6, wherein the semiconductor active layer is one of a low temperature polycrystalline silicon semiconductor, an amorphous silicon semiconductor, and an oxide semiconductor.

10. The flat plate type of image sensor of claim 1, wherein the visible light converter is disposed between the object and the photosensor unit.

11. The flat plate type of image sensor of claim 8, wherein the second protective layer or the sensor protective layer is formed of an organic material or an inorganic material.
